(19) United States
(12) Patent Application Publication
(10) Pub. No.: US 2008/0136436 A1
(43) Pub. Date: Jun. 12, 2008

(54) WAFER CHUCK, APPARATUS INCLUDING THE SAME AND METHOD FOR TESTING ELECTRICAL CHARACTERISTICS OF WAFER

(76) Inventor: Jun-Pyo Hong, Seoul (KR)

Correspondence Address: F. CHAU & ASSOCIATES, LLC, 130 WOODBURY ROAD, WOODBURY, NY, 11797, US

(21) Appl. No.: 11/950,788

(22) Filed: Dec. 5, 2007

(30) Foreign Application Priority Data
Dec. 11, 2006 (KR) 2006-125711

(51) Int. Cl. G01R 31/26; G01R 1/02

(52) U.S. Cl. 324/760

(57) ABSTRACT

Electrical characteristics of a wafer are tested using a probe card while the wafer is placed on a wafer chuck. The wafer chuck cools the wafer to a predetermined temperature to test the electrical characteristics of the wafer at the normal temperature. Inside the wafer chuck, a plurality of thermoelectric elements are disposed in parallel with the top surface of the wafer chuck and current is applied to the thermoelectric elements. The thermoelectric elements heat or cool the wafer according to the direction of the applied current. The wafer chuck may heat the wafer to a predetermined temperature to test the electric characteristics of the wafer at a high temperature. The top surface of the wafer chuck may be heated by a heating coil installed on the wafer chuck.

### CROSS-REFERENCE TO RELATED APPLICATION

This U.S. non-provisional patent application claims priority under 35 U.S.C § 119 of Korean Patent Application 2006-125711 filed on Dec. 11, 2006, the entirety of which is hereby incorporated by reference.

### BACKGROUND

The present disclosure relates to an apparatus and a method for testing electrical characteristics of a wafer. More specifically, the present disclosure is directed to a test apparatus and a test method using a thermoelectric element.

Generally, semiconductor devices are manufactured in a wafer state. Semiconductor devices that are manufactured on a wafer are tested to assure their reliability before being packaged. In this regard, the semiconductor manufacturing process usually includes a process of directly applying an electrical signal to the semiconductor devices on the wafer to finally test the semiconductor devices before being separated.

Similarly, an electrical contact process is conducted for semiconductor devices formed on a wafer in order to test their electrical characteristics, which process is called an electrical die sorting (EDS) test. Further, an apparatus for performing an EDS test is called a wafer probing machine. In such a wafer probing machine, a probe comes in contact with a metal pad formed on the surface of the semiconductor device to test the electrical characteristics of the semiconductor device. An apparatus for testing the electrical characteristics of a semiconductor device is disclosed in U.S. Pat. Nos. 6,118,290, 6,353,221, and 6,170,116.

Such a test is conducted under various conditions including a controlled temperature condition, taking into consideration the conditions of practical use. That is, the test is conducted at a high temperature condition of approximately 85 degrees centigrade and a normal temperature condition of approximately 25 degrees centigrade. A conventional test apparatus, however, is not equipped with a cooling unit and cools a wafer by natural cooling. For this reason, a long time is taken to cool a wafer. As a result, the test time is unavoidably increased.

### SUMMARY OF THE INVENTION

Exemplary embodiments of the present invention provide a test apparatus for testing the electrical characteristics of a wafer. In an exemplary embodiment, the test apparatus may include: a wafer chuck on which a wafer is placed during a process; a probe card provided over the wafer chuck for testing the electrical characteristics of the wafer, and a test head at which the probe card is installed, wherein the wafer chuck comprises: a housing in which a space is defined, the housing having a top surface on which the wafer is placed; and a temperature control unit installed in the housing and including a plurality of thermoelectric elements.

Exemplary embodiments of the present invention provide a wafer chuck on which a wafer is placed during a test process. In an exemplary embodiment, the wafer chuck may include: a housing in which a space is defined, the housing having a top surface on which the wafer is placed; and a temperature control unit installed in the housing and including a plurality of thermoelectric elements.

Exemplary embodiments of the present invention provide a method for testing the electric characteristics of a wafer using an apparatus including a wafer chuck on which a wafer is placed during a test process, a probe card provided over the wafer chuck for testing the electrical characteristics of the wafer, and a test head at which the probe card is installed. In an exemplary embodiment, the method for testing may include: controlling a temperature of the wafer to a preset temperature using a plurality of thermoelectric elements provided inside the wafer chuck; and causing a probe of the probe card to come in contact with a top surface of the wafer to test the electrical characteristics of the wafer.

### BRIEF DESCRIPTION OF THE DRAWINGS

Exemplary embodiments of the present invention will be understood in more detail from the following descriptions taken in conjunction with the accompanying drawings.

FIG. 1 illustrates a test apparatus according to an exemplary embodiment of the present invention.

FIG. 2 illustrates a wafer chuck according to an exemplary embodiment of the present invention.

FIGS. 3A and 3B show that a wafer is cooled using a wafer chuck according to an exemplary embodiment of the present invention.

FIGS. 4A and 4B show that a wafer is heated using a wafer chuck according to the an exemplary embodiment present invention.

FIG. 5 illustrates a wafer chuck according to an exemplary embodiment of the present invention.

FIGS. 6A and 6B show that a wafer is heated using a wafer chuck according to an exemplary embodiment of the present invention.

### DETAILED DESCRIPTION OF EXEMPLARY EMBODIMENTS

Exemplary embodiments of the present invention will now be described more fully hereinafter with reference to the accompanying drawings, in which exemplary embodiments of the present invention are shown. This invention, however, may be embodied in many different forms and should not be construed as limited to the exemplary embodiments set forth herein. Rather, these exemplary embodiments are provided so that this disclosure will be thorough and complete, and will fully convey the scope of the invention to those of ordinary skill in the art.

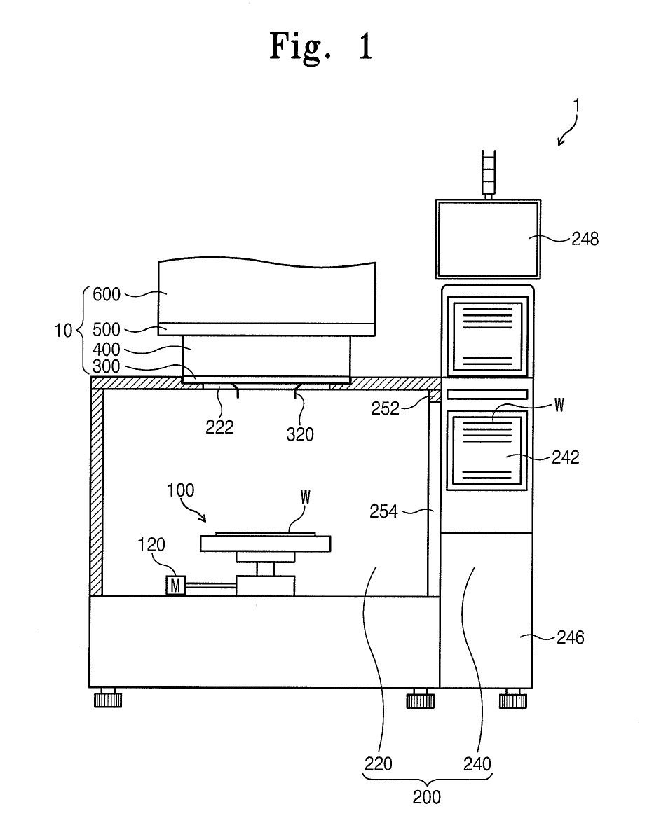

FIG. 1 illustrates a test apparatus 1 according to an exemplary embodiment of the present invention. The test apparatus 1 includes a wafer chuck 100, a body 200 and a test unit 10. The body 200 has a general shape of a rectangular parallelepiped, in which an empty interior space is formed. The body 200 includes a processing part 220 and a loader part 240, which are disposed side by side. A passage 254 is provided at a partition wall 252 for transferring a wafer W, and the partition wall 252 is disposed between the processing part 220 and the loader part 240. At the processing part 220, a wafer W is tested. At the loader part 240, a wafer W is aligned and loaded/unloaded on/from the wafer chuck 100. An aperture 222 is formed at the top surface of the body 200. A probe card 300, which will be described in detail hereinbelow, is installed at the aperture 222. A door (not shown) is installed at the front surface of the body 200, enabling structures installed inside the processing part 220 to be examined and maintained. A wafer W being processed is fixed to the wafer chuck 100, which moves linearly or rotatively by means of a chuck driver 120. The wafer chuck 100 travels between the processing part 220 and the loader part 240 through the passage 254 to load/unload a wafer W. During that process, the wafer chuck 100 moves linearly in a vertical/horizontal direction or rotatively such that a test area of the wafer W is located at a position in contact with a probe 320 of the probe card 300.

A worktable 242, on which a cassette accommodating a number of wafers W is placed, is disposed at one side of the loader part 240. An aligner (not shown) is disposed at the other side of the loader part 240 for aligning the wafers W. A transfer robot (not shown) is installed at the center of the loader part 240 for transferring a wafer W to the aligner from the cassette and transferring the aligned wafer W to the wafer chuck 100. The chuck driver 120 configured to move the wafer chuck 100 and a robot driver (not shown) configured to move the transfer robot disposed at the loader part 240 are precisely controlled by a controller 246. An operator may handle the controller 246 through controls (not shown) arranged on a handling panel 248.

The test unit 10 applies an electrical signal to a chip formed on a wafer W to test the electrical characteristics of the chip. During a process, the test unit 10 is disposed over the processing part 220. The test unit 10 includes a probe card 300, a pogo module 400, and a test head 600. The probe card 300 is inserted into the aperture 222 formed at the top surface of the body 200 to be fixedly installed at the body 200. The probe card 300 is manufactured from a disk-shaped printed circuit board (PCB). Probes 320 are installed at the bottom surface of the probe card 300 to protrude downwardly. During a test process, the probes 320 come in contact with one or more pads (not shown) formed on a wafer W.

The test head 600 is rotatably disposed over the body 200. A performance board 500 is installed on the bottom surface of the test head 600. A measuring unit (not shown) is disposed at the test head 600. The measuring unit applies an electrical signal to the performance board 500 to measure electrical characteristics of a target object.

The pogo module 400 is disposed between the performance board 500 and the probe card 300, thereby electrically connecting the performance board 500 and the probe card 300 to each other. The pogo module 400 may be fixedly installed at the body 200 or the test head 600.

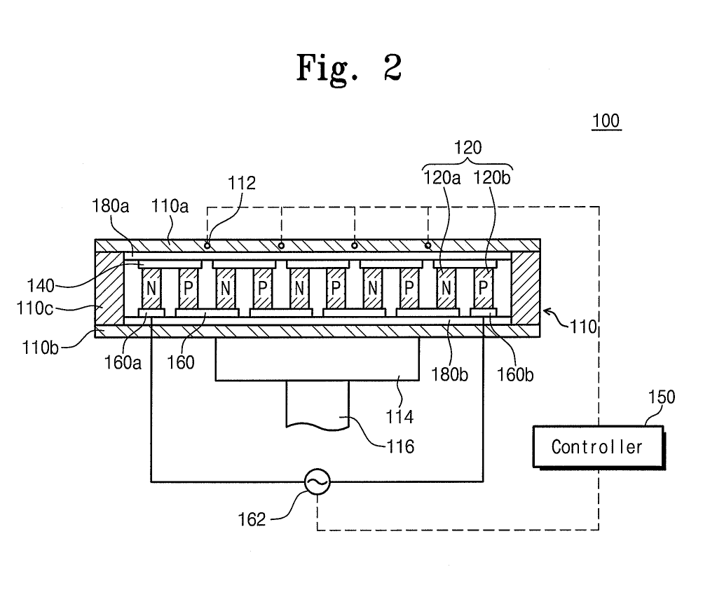

FIG. 2 illustrates a wafer chuck 100 according to an exemplary embodiment of the present invention. The wafer chuck 100 includes a housing 110 in which an empty interior space is formed, a plurality of thermoelectric elements 120 arranged inside the housing 110, and first and second heating plates 140 and 160 provided to connect the thermoelectric elements 120 to each other.

The housing 110 includes a top plate 110a on which a wafer W (not shown in FIG. 2) is placed, a bottom plate 110b disposed below the top plate 110a, and a side plate 110c provided to connect the top plate 110a with the bottom plate 110b. Since the top plate 110a and the bottom plate 110b absorb external heat and transfer the absorbed heat to the inside or release the internal heat to the outside, the top plate 110a and the bottom plate 110b are made of a material having a high heat transfer coefficient.

A plurality of thermoelectric elements 120 are disposed at a space defined in the housing 110, and the thermoelectric elements 120 are heated or cooled by the Peltier effect. The Peltier effect is a phenomenon that when current flows to a circuit including two different kinds of metals, one junction is cooled and the other is heated. In the Pettier effect, cooling and heating are interchanged by varying the current flow direction.

The thermoelectric elements 120 are arranged along the top plate 110a. The thermoelectric elements 120 include N-type elements 120a and P-type elements 120b that are alternately arranged. The N-type elements 120a and the P-type elements 120b are connected to each other through the first heating plate 140 and the second heating plate 160.

As illustrated in FIG. 2, the first heating plate 140 is connected to the top side of the thermoelectric elements 120, and the second heating plate 160 is connected to bottom side thereof. The top of the N-type element 120a is connected to one side of the first heating plate 140, and the top of the P-type element 120b is connected to the other side of the first heating plate. The bottom of the P-type element 120b connected to the other side of the first heating plate 140 is connected to one side of the second heating plate 160, and the next N-type element 120a is connected to the other side of the second heating plate 160. The thermoelectric elements 120, which are alternately arranged inside the housing 110, are connected to each other in series by a repetition of the first heating plate 140 and the second heating plate 160.

As described hereinabove, the first and second heating plate 140 and 160 are cooled or heated by the Pettier effect. A material having a high heat transfer coefficient is used to easily cool or heat the first and second heating plates 140 and 160.

The bottom of the N-type element 120a, which is disposed at the left end inside the housing 110 to be adjacent the side plate 110c, is connected to a left terminal 160a. The bottom of the P-type element 120b, which is disposed at the right end inside the housing 110 to be adjacent the side plate 110c, is connected to a right terminal 160b. A power source 162 is connected to the left terminal 160a and the right terminal 160b. Thus, the left and right terminals 160a and 160b and the power 162 constitute one closed circuit. The power source 162 is a direct current (DC) power source, which applies current in one direction. A controller 150 connected to the power source 162 may change the current direction to a clockwise or counterclockwise direction relative to the circuit shown in FIG. 2.

A top insulating plate 180a is provided on the top surface of the first heating plate 140, and a bottom insulating plate 180b is provided on the bottom surface of the second heating plate 160. The top insulating plate 180a and the top plate 110a are disposed, one on top of the other in a vertical direction, and the bottom insulating plate 180b and the bottom plate 110b are disposed, one on top of the other in the vertical direction. The top and bottom insulating plates 180a and 180b are each made of an insulating material. The top insulating plate 180a electrically insulates the top plate 110a from the first heating plate 140D and the bottom insulating plate 180b electrically instates the bottom plate 110b from the second heating plate 160.

When the first heating plate 140 is cooled, the top insulating plate 180a transfers the heat of the top plate 110a to the first heating plate 140. When the first heating plate 140 is heated, the top insulating plate 180a transfers the heat of the first heating plate 140 to the top plate 110a. Accordingly, the top insulating plate 180a is made of an insulating material having a high heat transfer coefficient. Because the bottom insulating plate 180b serves the same function as the top insulating plate 180a, it is also made of an insulating material having a high heat transfer coefficient.

A plurality of sensors 112 are provided inside the top plate 110a for sensing a temperature of the top plate 110a or the temperature of a wafer W placed on the top plate 110a. The sensors 112 are disposed to correspond to portions of the top plate 110a located between the adjacent first heating plates 140. Because the first heating plate 140 is heated or cooled according to the flow of current applied from the power source 162, a sensor 112 disposed to correspond to a portion of the top plate 110a located over the first heating plates 140 may have difficulty in accurately sensing a temperature of the top plate 110a or a wafer W.

The sensors 112 are connected to the controller 150. According to the temperature measured using the sensors 112, the controller 150 may cut off current applied from the power source 162 or may change the direction of the current flow.

A support shaft 116 is connected to the bottom of the bottom plate 110b by a connector 114.

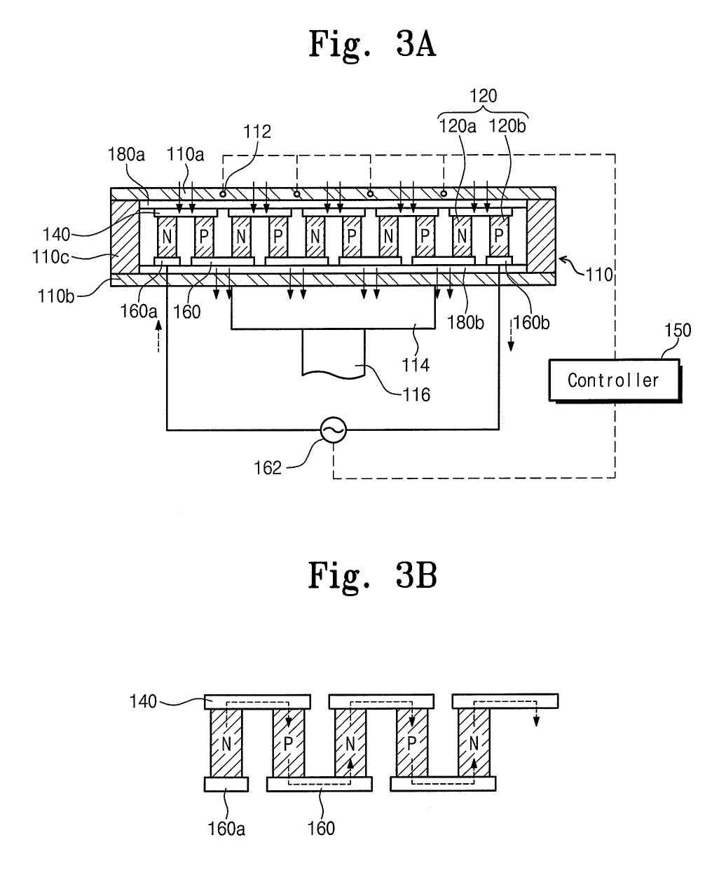

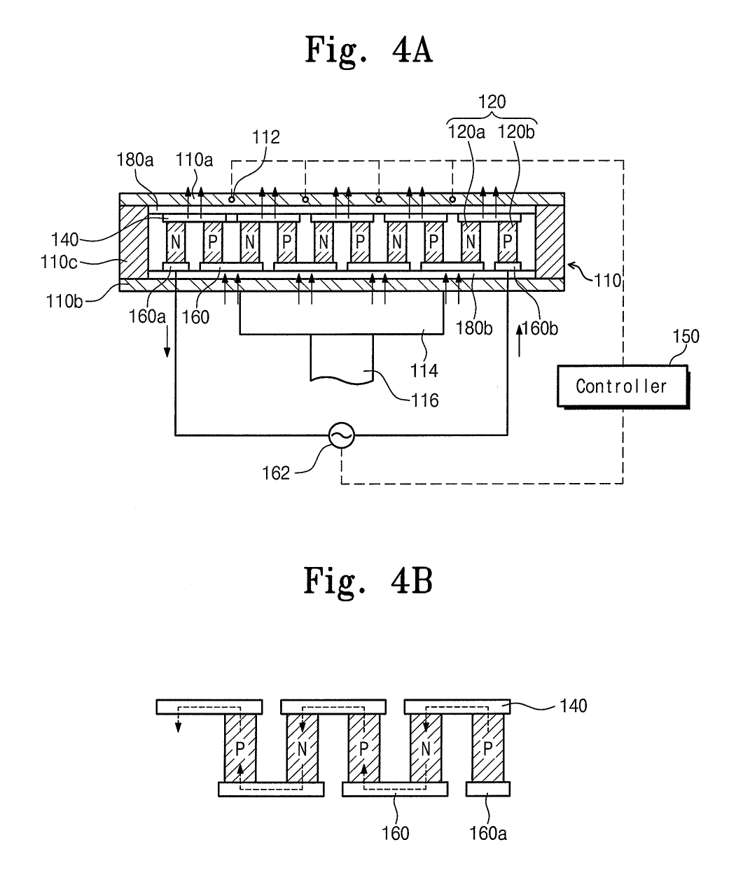

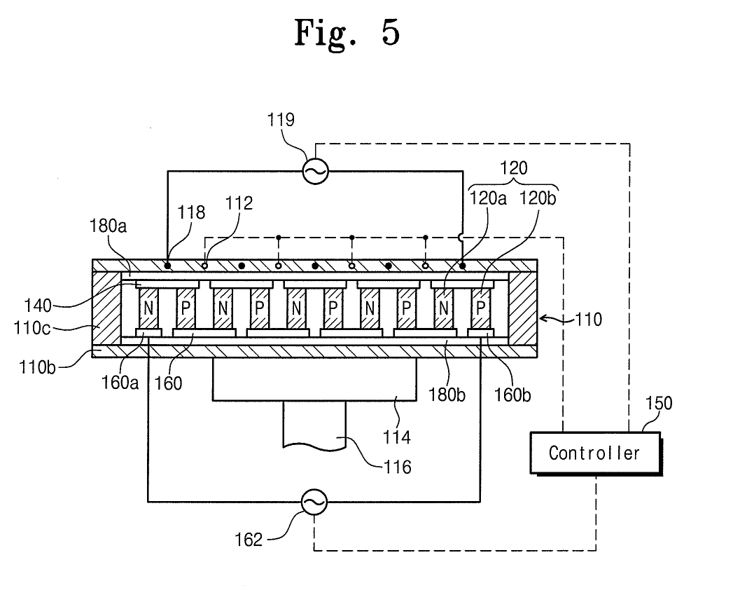

A method of operating the wafer chuck 100 will now be described with reference to FIGS. 3A through 4B. FIGS. 3A and 3B show that a wafer W is cooled using the wafer chuck 100 according to an exemplary embodiment of the present invention, and FIGS. 4A and 4B show that a wafer W is heated using the wafer chuck 100 according to an exemplary embodiment of the present invention.

Initially, a method for testing electrical characteristics of a wafer W at a normal temperature will be described. As illustrated in FIG. 3A, current is caused to flow in a clockwise direction from the power source 162 using the controller 150. The applied current is applied to an N-type element 120a through a left terminal 160a, applied to a P-type element 120b through a first heating plate 140, and applied to an N-type element 120a through a second heating plate 160. Through the series of such operations, the current flows as shown in FIG. 3B.

On the basis of the first heating plate 140, current flows to the P-type element 120b from the N-type element 120a and the first heating plate 140 is cooled by the Peltier effect. On the basis of the second heating plate 160, current flows to the N-type element 120a from the P-type element 120b and the second heating plate 160 is heated by the Peltier effect.

Thus, the first heating plate 140 absorbs the heat of the top plate 110a through the top insulating plate 180a and the second heating plate 160 releases the heat to the bottom plate 110b through the bottom insulating plate 180b. As a result, a wafer W (not shown) placed on a top plate 110a is cooled. The arrows shown in FIG. 3A represent the direction of heat flow in the test apparatus.

Sensors 112 sense a temperature of the top late 110a or the wafer W, and the sensed temperature is transmitted to the controller 150 after being converted to a signal. When the temperature reaches a preset temperature, the controller 150 cuts off the power 162 to stop cooling the wafer W. When the cooling of the wafer W is completed, the electrical characteristics of the wafer W are tested by means of the above-described method and apparatus shown in FIG. 1.

Next, a method for testing the electrical characteristics of a wafer W at a high temperature will be described. As illustrated in FIG. 4A, current is caused to flow in a counterclockwise direction from the power source 162 using the controller 150. The applied current is applied to a P-type element 120b through a right terminal 160b, applied to an N-type element 120a through a first heating plate 140, and applied to a P-type element 120b through a second heating plate 160. Through the series of such operations, the current flows as shown in FIG. 4B.

On the basis of the first heating plate 140, current flows to the N-type element 120a from the P-type element 120b and the first plate 140 is heated by the Pettier effect. On the basis of the second heating plate 160, current flows to the P-type element 120b from the N-type element 120a and the second heating plate 160 is cooled by the Peltier effect.

Thus, the first heating plate 140 releases heat to the top plate 110a through the top insulating plate 180a and the second heating plate 160 absorbs the heat of the bottom plate 110b through the bottom insulating plate 180b. As a result, a wafer W (not shown) placed on a top plate 110a is heated. The arrows shown in FIG. 4A represent the direction of heatflow in the test apparatus.

Similarly, sensors 112 sense a temperature of the top plate 110a or the wafer W, and the sensed temperature is transmitted to a controller 150 after being converted to a signal. When the temperature reaches a preset temperature, the controller 150 cuts off the power 162 to stop heating the wafer W. When the heating of the wafer W is completed, electrical characteristics of the wafer W are tested by means of the above-described method and apparatus shown in FIG. 1.

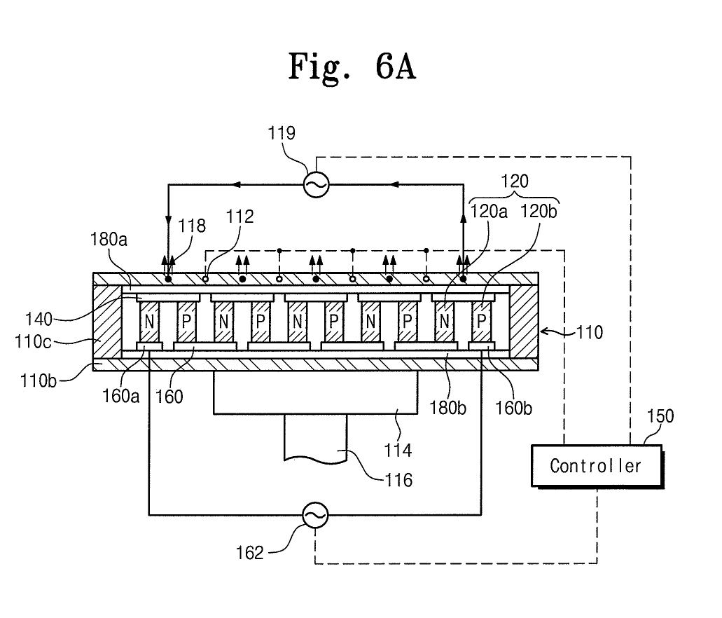

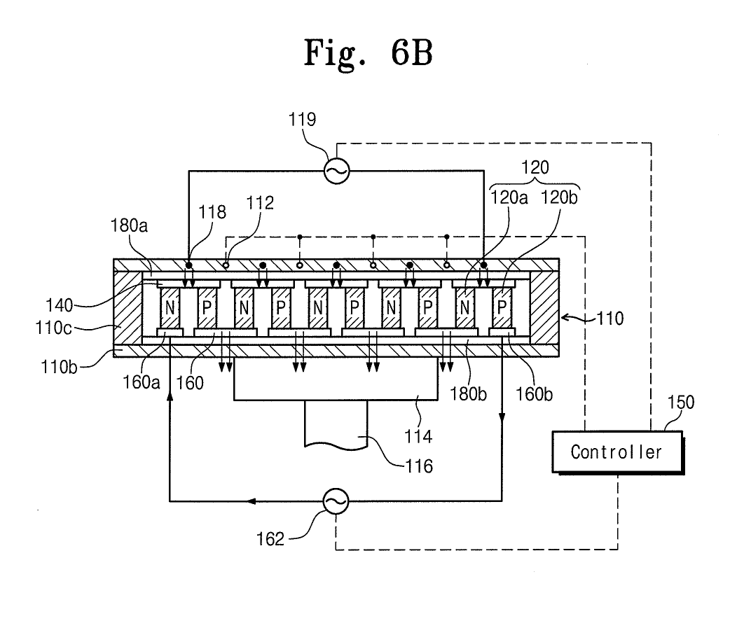

FIG. 5 illustrates a wafer chuck 100 according to an exemplary embodiment of the present invention, and FIGS. 6A and 6B show that a wafer is heated using a wafer chuck according to an exemplary embodiment of the present invention. A wafer is heated using a heating coil 118 in this exemplary embodiment, instead of being heated using the thermoelectric elements 120 in the above-described exemplary embodiment.

The heating coil 118 is installed inside the top plate 110a, and a power source 119 is connected to both ends of the heating coil 118. The power source 119 operates or stops by means of the controller 150. Although the shape of the heating coil 118 is not shown in the figures, it is well known to those of ordinary skill in the art. In any event, the shape of the heating coil 118 is provided to uniformly heat a wafer W (not shown).

Initially, a method for testing the electrical characteristics of a wafer W at a high temperature will be described. As illustrated in FIG. 6A, when current is applied to a heating coil 118 from a power source 119 using a controlter 150, the heating coil 119 releases heat to the top plate 110a and a wafer W (not shown) placed on the top plate 110a is heated. The arrows shown in FIG. 6A represent the direction of heat flow in the test apparatus.

The sensors 112 sense the temperature of the top plate 110a or the wafer W, and the sensed temperature is transmitted to the controller 150 after being converted to a signal. When the temperature reaches a preset temperature, the controller 150 cuts off the power source 119 to stop heating the wafer W. When the heating of the wafer W is completed, the electrical characteristics of the wafer W are tested by means of the above-described method and apparatus shown in FIG. 1.

Next, the electrical characteristics of the wafer W at the normal temperature are tested. FIG. 6B illustrates a process of cooling a wafer W at the normal temperature, which is identical to that illustrated in FIG. 3A and will not be described in further detail.

As described above, a wafer W is cooled to a preset temperature using thermoelectric elements 120 to shorten the time required for cooling the wafer W. Moreover, a wafer W is heated to a preset temperature using thermoelectric elements 120 without a separate heating apparatus. In addition, thermoelectric elements 120 are provided inside a housing 110 to reduce the overall footprint of a test apparatus 1.

Exemplary embodiments of the present invention have advantages such as follows: (1) time required for cooling a wafer W is reduced; (2) thermoelectric elements may be used to heat a wafer W; and (3) thermoelectric elements are provided inside a wafer chuck to reduce the volume of a test apparatus.

Although the present invention has been described in connection with the exemplary embodiments of the present invention illustrated in the accompanying drawings, it is not limited thereto. It will be apparent to those of ordinary skill in the art that various substitutions, modifications and changes may be made without departing from the scope and spirit of the present invention.

What is claimed is:

1. An apparatus for testing electrical characteristics of a wafer, comprising:
a wafer chuck on which a wafer is placed during a test process;
a probe card provided over the wafer chuck for testing electrical characteristics of the wafer; and
a test head at which the probe card is installed,
wherein the wafer chuck comprises:
a housing in which a space is defined, the housing having a top surface on which the wafer is placed; and
a temperature control unit installed in the housing and including a plurality of thermoelectric elements.

2. The apparatus of claim 1, wherein the plurality of thermoelectric elements are arranged inside the housing to be parallel with the top surface of the housing; and
the temperature control unit comprises:
first heating plates by which top sides of the plurality of thermoelectric elements are connected to each other;
second heating plates by which bottom sides of the plurality of thermoelectric elements are connected to each other; and
a power source adapted to apply current to the plurality of thermoelectric elements.

3. The apparatus of claim 2, wherein the plurality of thermoelectric elements comprises a plurality of N-type elements and a plurality of P-type elements;
one side of each of the first heating plates is connected to one of the plurality of N-type elements, and the other side of each of the first heating plates is connected to one of the plurality of P-type elements; and
the first heating plates are cooled when the current applied from the power source flows to the plurality of P-type elements connected to the first heating plates from the plurality of N-type elements connected to the first heating plates, and are heated when the current applied from the power source flows to the plurality of N-type elements connected to the first heating plates from the plurality of P-type elements connected to the first heating plates.

4. The apparatus of claim 2, wherein the temperature control unit further comprises;
a heating coil provided on the first heating plates for heating the top surface of the housing.

5. The apparatus of claim 2, further comprising:
at least one temperature sensor provided at the top surface of the housing for sensing a temperature of the top surface; and
a controller provided for controlling the power source in response to a sensing signal from the temperature sensor.

6. The apparatus of claim 2, wherein the housing comprises:
a top plate, disposed over the first heating plates, on which the wafer is placed.

7. The apparatus of claim 6, wherein the wafer chuck further comprises:
a top insulating plate disposed between the first heating plates and the top plate to insulate the first heating plates from the top plate.

8. A wafer chuck on which a wafer is placed during a test process, the wafer chuck comprising:
a housing in which a space is defined, the housing having a top surface on which the wafer is placed; and
a temperature control unit installed in the housing and including a plurality of thermoelectric elements.

9. The wafer chuck of claim 8S wherein the plurality of thermoelectric elements are arranged inside the housing to be parallel with the top surface of the housing; and
the temperature control unit comprises:
first heating plates by which top sides of the plurality of thermoelectric elements are connected to each other;
second heating plates by which bottom sides of the plurality of thermoelectric elements are connected to each other; and
a power supply adapted to apply current to the plurality of thermoelectric elements.

10. The wafer chuck of claim 9, wherein the plurality of thermoelectric elements comprises a plurality of N-type elements and a plurality of P-type elements;
one side of each of the first heating plates is connected to one of the plurality of N-type elements, and the other side of each of the first heating plates is connected to one of the plurality of P-type elements; and
the first heating plates are cooled when the current applied from the power source flows to the plurality of P-type elements connected to the first heating plate from the plurality of N-type elements connected to the first heating plates, and are heated when the current applied from the power source flows to the plurality of N-type element connected to the first heating plates from the plurality of P-type element connected to the first heating plates.

11. The apparatus of claim 9, wherein the temperature control unit further comprises;
a heating coil provided on the first heating plates for heating the top surface of the housing.

12. The wafer chuck of claim 9, further comprising:
at least one temperature sensor provided at the top surface of the housing for sensing a temperature of the top surface; and
a controller provided for controlling the power source in response to a sensing signal from the temperature sensor.

13. The wafer chuck of claim 9, wherein the housing comprises:
a top plate, disposed over the first heating plates, on which the wafer is placed.

14. The apparatus of claim 13, further comprising:
a top insulating plate disposed between the first heating plates and the top plate to insulate the first heating plates from the top plate.

15. A method for testing electric characteristics of a wafer using an apparatus including a wafer chuck on which a wafer is placed during a test process, a probe card provided over the wafer chuck for testing electrical characteristics of the wafer, and a test head at which the probe card is installed, the method comprising:
controlling a temperature of the wafer to a preset temperature using a plurality of thermoelectric elements provided inside the wafer chuck; and
causing a probe of the probe card to come in contact with a top surface of the wafer to test electrical characteristics of the wafer.

16. The method of claim 15, wherein the plurality of thermoelectric elements are disposed in parallel with a top surface of the wafer chuck;
The method further including providing first heating plates to connect top sides of the plurality of thermoelectric elements to each other, and providing second heating plates to connect bottom sides of the plurality of thermoelectric elements to each other.

17. The method of claim 16, wherein the plurality of thermoelectric elements comprises a plurality of N-type elements and a plurality of P-type elements,
one side of each of the first heating plates is connected to one of the plurality of N-type elements, and the other side of each of the first heating plates is connected to one of the plurality of P-type elements; and
the first heating plates are cooled when the current applied from a power source flows to the plurality of P-type elements connected to the first heating plates from the plurality of N-type elements connected to the first heating plates.

18. The method of claim 17, further comprising:
heating the wafer to a preset temperature; and
testing electrical characteristics of the heated wafer using the probe card.

19. The method of claim 18, wherein the wafer is heated using the plurality of thermoelectric elements;
the first heating plates are heated when the current applied from the power source flows to the plurality of N-type elements connected to the first heating plates from the plurality of P-type elements connected to the first heating plates; and
the wafer is heated using the first heating plates.

20. The method of claim 18, wherein the wafer is heated by a heating coil provided on the first heating plates.
